(19) United States
(12) Patent Application Publication
(10) Pub. No.: US 2006/0126691 A1
(43) Pub. Date: Jun. 15, 2006

(54) Dual platform semiconductor laser device

(75) Inventors: Borlin Lee, Hsin-chu (TW); Chun-Han Wu, Hsin-chu (TW); Jin-Shan Pan, Hsin-chu (TW); Hung-Ching Lai, Hsin-chu (TW)

Correspondence Address: HDSL, 4331 STEVENS BATTLE LANE, FAIRFAX, VA, 22033, US

(73) Assignee: True Light Corporation

(21) Appl. No.: 11/302,336

(22) Filed: Dec. 14, 2005

(30) Foreign Application Priority Data
Dec. 15, 2004 (TW) 093138836

(51) Int. Cl. H01S 5/00

(52) U.S. Cl. 372/43.01

(57) ABSTRACT

A dual platform semiconductor laser device includes a laser chip layer, two independent platforms formed on the laser chip layer and defining a light emitting active area platform and a wire bonding platform, a planarized dielectric layer filled between the independent platforms, a protective layer disposed at the dielectric layer and including a contact area hole corresponding to the first independent platform, coated onto the metal layer at the protective layer and coupled to the first independent platform, and extended to the second independent platform to form a pad for wire bonding the first independent platform. The independent platforms define the second independent platform for wire bonding, and its capacitance is modulated to provide a stronger wire bonding strength, and the dielectric layer filled at the external sides of the two platforms lowers the wire connected metal capacitance and obtain a planarized surface for producing the metal layer easily.

### BACKGROUND OF THE INVENTION

1. Field of the Invention

The present invention relates to a dual platform semiconductor laser device, and more particularly to a technical area that relates to an oxide confined vertical-cavity laser having a dual platform semiconductor structure.

2. Description of Prior Art

Optical information and communication systems provide a major method for moving huge data in a high speed, and one of the main components of such optical information and communication systems is an optical transceiver. At the data transmitting end, an optical transceiver is provided for translating a data in the form of electric signals (such as a digital data in the form of 0 and 1) into an optical signal which is suitable to be transmitted by a transmission medium (such as an optical fiber cable). At the data receiving end, the optical transceiver translates the received optical signal back into a data in the form of electric signals. One of the major components of the foregoing optical transmitter is an optical transmitter for transmitting optical data, and typical optical transmitters for the preferred embodiment are light emitting diode (LED) and semiconductor laser diode (LASER), wherein the semiconductor laser diode (LASER) has a higher transmission speed, and thus becoming the subject for the main development and applications of the present optical communication system.

Most of the present optical transmitters used for optical information communication systems are surface emitting semiconductor laser diode (LASER) such as a vertical-cavity surface emitting laser (VCSEL). As its name suggests, the laser beam is emitted vertically from the surface of the component, characterized in that the upper and lower distributed Bragg reflectors (DBR) are used to define a laser cavity. Unlike the edge emitting laser, the surface emitting laser omits the complicated process of producing laser mirrors of the edge emitting laser by the cracking and dry etching methods. Furthermore, the vertical-cavity surface emitting laser (VCSEL) has the following advantages:

(1) The low scattered circular laser beam is coupled to the optical fiber easily.

(2) The VCSEL has a high speed modulation function that facilitates high speed optical fiber network transmissions.

(3) The manufacturing process technology of components is suitable for mass production.

(4) Before the epitaxy is cut and packaged, the properties of each crystal grain of the whole wafer are tested by the wafer-lever testing, and thus it incurs a lower cost.

(5) A one-dimensional (1D) or two-dimensional (2D) laser matrix can be produced for facilitating a serial or parallel optical fiber transmission.

The structure of a vertical-cavity surface emitting laser (VCSEL) is generally divided into four types: Etched Air-Post, Ion Implanted, Regrowth Buried Heterostruture, and Oxide Confined, and most commercial products adopt the Ion Implanted type, because its manufacturing process is simple and suitable for mass production. However, when the ion implant technology is used, its implant area cannot be too close to the active layer of the surface emitting laser, otherwise the high-energy particles may destroy the material of the active layer and deteriorate the properties of the laser components, and thus the ion-implant vertical-cavity surface emitting laser (VCSEL) is not suitable for high frequency operations. Therefore, the commercial laser products tend to be developed as oxide confined vertical-cavity surface emitting lasers (VCSEL), whose properties are better than those of the ion implant lasers mainly because its light emitting active area is narrower, and thus obtaining a lower critical current, and a high-quantum efficient and low critical voltage. As to the oxide confined technology, an aluminum gallium arsenide (AlGaAs) with a high aluminum content is introduced adjacent to the active layer and selectively etched to expose it in a high-temperature water vapor, and then the AlGaAs layer with a high aluminum content will be converted into an insulating aluminum oxide dielectric layer to achieve the effect of confining currents and photons. After a device is selectively etched, the device will have a non-planarized surface which may produce a crack and cause a poor yield rate of the device, when the metal electrode is produced on a non-planarized surface.

To respond to the existing shortcomings of the foregoing oxide confined vertical-cavity surface emitting laser (VCSEL), different manufacturing methods are developed to produce VCSEL, such as those disclosed in U.S. Pat. Publication No. 2003/0123502 (R.O.C. Pat. Publication No. 200306043), U.S. Pat. No. 6,658,040 (R.O.C. Pat. No. 151547), and R.O.C. Pat. No. 192770. These patented technologies mainly adopt a trench oxide confined technology to produce the VCSEL, and thus the requirements for the etching equipments will be higher, and the inductively coupled plasma (ICP) etching system must be used. Of course, the equipments and manufacturing costs will be more expensive. Further, U.S. Pat. Nos. 6,645,848 and 6,570,905, R.O.C. Pat. No. 130588, and R.O.C. Pat. Publication No. 580785 disclosed the methods of producing VCSEL by an oxide confined platform. It is worth to point out that the technical contents related to oxide confined vertical-cavity surface emitting lasers (VCSEL) and disclosed in these prior-art patented technologies adopt the single-platform semiconductor as the basic architecture to build the light emitting active area of the vertical-cavity surface emitting laser (VCSEL).

It is worth to note that U.S. Pat. No. 6,645,848 issued to John R. Joseph, et al, U.S. Pat. No. 6,658,040 (R.O.C. Pat. No. 151547) issued to Syn-Yem Hu et al, and U.S. Pat. No. 6,570,905 issued to Karl Joachim Ebeling disclosed the same aforementioned methods of using a single-platform semiconductor as the basic architecture to build the light emitting active area of the vertical-cavity surface emitting laser (VCSEL) and further using a dielectric material to fill a metal layer after the light emitting active area is produced, so as to create a wire bonding area electrically coupled to the light emitting active area. However, the wire bonding area created by filling a dielectric material has a weaker mechanical stress due to the properties of the dielectric material. As a result, films often cracks during the wire bonding process, and the effect of the wire bonding will be affected adversely, or even worse, the wire bonding cannot be completed.

### SUMMARY OF THE INVENTION

The present invention is to provide a dual platform semiconductor laser device that forms a first independent platform as the platform of the light emitting area and a second independent platform as a wire bonding platform directly on the structure of a laser semiconductor material to go with the oxide layer, dielectric layer, protective layer, and metal layer, so as to produce an oxide confined dual platform for the vertical-cavity surface emitting laser semiconductor laser device.

Another, the present invention is to provide a dual platform semiconductor laser device, and the dual platform structure of the first independent platform and the second independent platform is etched and formed directly onto the structure of the laser semiconductor material to produce an independent light emitting active area platform and a wire boding platform, so as to independently design the structure of the light emitting active area platform and the wire bonding platform.

Further, the present invention is to provide a dual platform semiconductor laser device, wherein the second independent platform is formed directly on the semiconductor structure, so that the ion implant can adjust the capacitance as well as obtaining a higher mechanical stress for the wire bonding.

Another further, the present invention is to provide a dual platform semiconductor laser device, such that a dielectric material is filled between the exteriors of the dual platforms to form a dielectric layer for obtaining a better surface planarization and facilitating the production of the metal layer and lowering the connected metal capacitance.

To achieve the foregoing objectives, a dual platform semiconductor laser device of the invention comprises a laser chip layer, a bottom electrode layer (with a cathode layer), coupled to the laser chip layer, a first independent platform, etched and formed on the laser chip layer, a second independent platform, etched and formed on the laser chip layer, an insulating oxide layer, formed between the first independent platform and second independent platform, a dielectric layer filled between the exteriors of the first independent platform and second independent platform to form a planarized surface, a protective layer disposed at the surface of the dielectric layer and including a contact area hole corresponding to the first independent platform and a metal layer plated onto the surface of the protective layer and coupled to the first independent platform, and using the second independent platform to form a pad of the first independent platform as a P electrode layer.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a lateral cross-sectional view of a laser device according to a first preferred embodiment of the present invention;

FIG. 2 is a top view of a laser device according to a first preferred embodiment of the present invention; and

FIG. 3 is a lateral cross-sectional view of a laser device according to a second preferred embodiment of the present invention.

### DETAILED DESCRIPTION OF THE INVENTION

The technical characteristics, features and advantages of the dual platform semiconductor laser device in accordance with the present invention will become apparent in the following detailed description of the preferred embodiments with reference to the accompanying drawings.

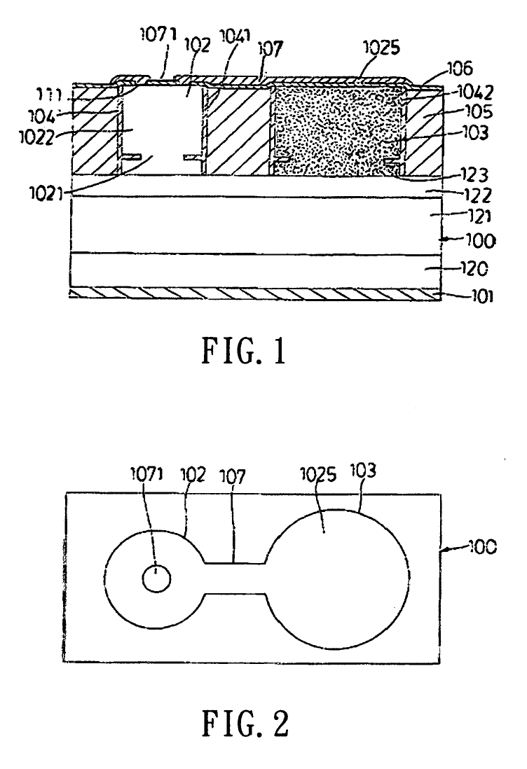

Referring to FIGS. 1 and 2 for the lateral cross-sectional view and the top view of a dual platform semiconductor laser device according to a preferred embodiment of the present invention, the dual platform semiconductor laser device of the invention comprises a laser chip layer (VCSEL) 100, a bottom electrode layer 101 (with a cathode layer), a first independent platform 102, a second independent platform 103, an oxide layer 104, a dielectric layer 105, a protective layer 106 having a contact area hole 111 and a metal layer 107. From the bottom up, there are a bottom electrode layer 101, a laser chip layer (VCSEL) 100, a light emitting active area platform 102, a wire bonding area platform 103, a light emitting active area platform 102, a wire bonding platform 103, an oxide layer 104 forming an insulating area, a dielectric layer 105, a protective layer 106, and a metal layer 107.

In the preferred embodiment of the present invention, the laser chip layer is a laser chip layer (VCSEL) 100 of an oxide confined vertical-cavity surface emitting laser (VCSEL), which is a laser semiconductor material with 3˜5 epitary layers. In the preferred embodiment as shown in FIG. 1, the laser chip layer 100 of the laser semiconductor material comprises a substrate 120, a first distributed Bragg reflector (DBR) 121 grown at a distal surface of the substrate 120 according to the continuous epitary, an active area 122, and a second distributed Bragg reflector (DBR) 123, and a first independent platform 102 and a second independent platform 103 etched and formed directly by the second distributed Bragg reflector (DBR) 123 into a dual platform with a gap in between, so as to obtain a dual semiconductor platforms as the structure of the light emitting active area and the wire bonding area of a conductor laser.

In this preferred embodiment of the present invention, the substrate 120 is made of an n+GaAs material, and the first distributed Bragg reflector (DBR) 121 is made of an N-DBRs expitary material, and the second distributed Bragg reflector (DBR) 123 is made of a P-DBRs expitary material.

The first independent platform 102 etched and formed directly from the laser chip layer 100 of the foregoing laser conductor material is a semiconductor structure that has not gone through the ion implant process, and the oxide layer 104 produces a light emitting active area to define a light emitting active platform. The second independent platform 103 is a semiconductor structure that has gone through the ion implant process as shown in FIG. 1 to work together with the oxide layer 104 to produce an area platform of a pad for providing the wire bonding of a light emitting active area to define the wire bonding platform, unlike the prior art which uses a dielectric material filling as the structure of the wire boding platform constructing foundation.

In the structure of a preferred embodiment of the present invention, the second independent platform 103 etched and formed directly on the laser chip layer 100 carries out several important functions, and one of these functions provides an area platform base of a pad for the wiring bonding in the light emitting active area. In the structure of a preferred embodiment, another important function is to modulate the capacitance of the second independent platform 103 as a wire bonding platform by the ion implant process. The structure of the second independent platform 103 provides another function which gives a higher mechanical stress during the wire bonding process.

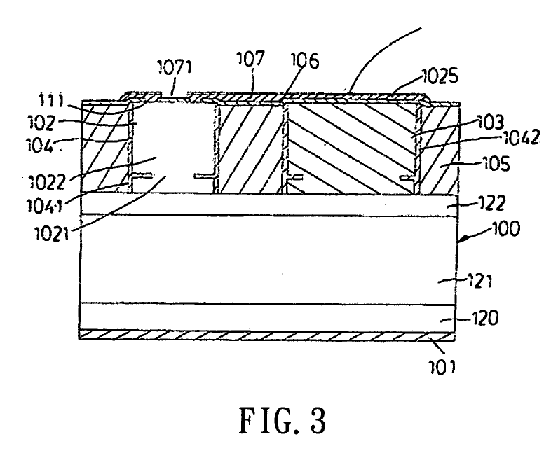

In the structure of another preferred embodiment, the second independent platform 103 may not go through the ion implant process as shown in FIG. 3, and the second independent platform 103 is etched and formed on a laser chip layer 100 made of a laser semiconductor material to meet the low-cost requirement.

The oxide layer 104 uses an oxidizing material to produce an insulating area in the first independent platform 102 and the second independent platform 103 by the oxidation process. By the oxidation of the oxide layer 104, an oxide confined hole 1021 including the insulating area is produced in the first independent platform 102, and thus the structure of a light emitting active area 1022 disposed at the first independent platform 102 as the light emitting active area is formed to correspond with the active area 122 of a light producing area to carry out a vertical light emission.

The oxide layer 104 also forms an oxide confined hole 1031 including an insulating area at the second independent platform 103 to define the second independent platform 103 as an area for the pad.

The second independent platform 103 is preferably in a circular shape, but also could be in other shapes or areas such as square, trapezium, annular, and ellipse, etc. However, the shape and area of the second independent platform 103 should not constitute a limitation to the present invention.

The oxide layer 104 according to this preferred embodiment adopts an isolable layer preferably an insulating area formed by the oxidation of an oxidizing material. It is worth to note that the oxide layer 104 could be any isolable layer formed by an isolable material, which is any isolable layer formed by a material capable of forming the insulating area, and the oxide confined hole 1021 produced on the platform 102, 103.

The dielectric layer 105 is filled on the surface of the laser chip layer (VCSEL) 100 between the exteriors of the first independent platform 102 and the second independent platform 103 to match with the etching process to obtain a planarized surface corresponding to the top surfaces of the first independent platform 102 and the second independent platform 103 easily, so as to facilitate the coating of the protective layer 106 and metal layer 107. Therefore, the filling of the dielectric layer 105 can lower the wire connected metal capacitance between the light emitting area and the wire bonding area.

A film plated onto the surface of the dielectric layer 105 and the protective layer 106 formed at the top surfaces of the first independent platform 102 and second independent platform 103 provides an insulating layer to protect the surface of the dielectric layer 105. The protective layer 106 at its distal surface includes a contact area hole 111 corresponding to the position of the light emitting active area 1022 of the first independent platform 102 and used for the electrode contact of the metal layer 107.

In the structure of the preferred embodiment, the contact area hole 111 is preferably a circular hole, but also could be other continuous geometric shape such as a square, a trapezium, a rhombus, and an ellipse, etc. However, the shape of the contact area hole 111 should not constitute a limitation to the present invention. The contact area hole 111 penetrates through the protective layer 106 to form an exposed area of the first independent platform 102 for integrating the metal layer 107.

In the foregoing preferred embodiment, the protective layer 106 is made of a dielectric material such as silicon nitride (SiN) or silicon oxide (SiO2) and coated onto the dielectric layer 105 and the surfaces of the first independent platform 102 and second independent platform 103 in the form of films, so as to form a non-conductive protective layer.

The metal layer 107 provides a first independent platform 102 of a light emitting active area platform disposed on the surface of the dielectric layer 105 and electrically coupled to a P electrode layer (with a anode layer), and the metal layer 107 is disposed at an end of the first independent platform 102 having a light emitting hole 1071. In the meantime, the metal layer 107 is penetrated through the contact area hole 111 and coupled to the top surface of the first independent platform 102, and an end of the metal layer 107 is extended to the second independent platform 103, which acts as the basis of the second independent platform 103 for the wire bonding platform to produce a light emitting active area platform for the pad 1025 of wiring the P electrode layer.

The external diameter of the light emitting hole 1071 is smaller than the internal diameter of the contact area hole 111, and the diameter of the contact area hole 111 corresponds to the installation of the oxide confined hole 1021 of the light emitting active area platform 102 as shown in FIGS. 1 and 2, so as to correspond to the active area 122 of the light producing area to carry out the vertical light emission.

The metal layer 107 is a metal film layer made of an electrically conductive material for coupling the first independent platform 102 that acts as a light emitting active area platform, and forming a P electrode layer pad 1025 at the surface of the second independent platform 103. The metal layer 107 of the preferred embodiment is made of an electrically conductive material such as gold, silver, copper and other electrically conductive mixtures.

The oxide confined dual platform vertical-cavity surface emitting laser (VCSEL) and its manufacturing process in accordance with the present invention are illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

1. A dual platform semiconductor laser device, comprising:
a laser chip layer;
a bottom electrode layer including a cathode layer, coupled to the laser chip layer;
a first independent platform, etched and formed on the laser chip layer;
a second independent platform, etched and formed on the laser chip layer;
an oxide layer, having an oxide confined insulating area and disposed at the first independent platform and the second independent platform;
a dielectric layer, filled between the exteriors of the first independent platform and the second independent platform, and forming a planarized surface on the surface of the laser chip layer;
a protective layer, disposed on the surface of the dielectric layer and including a contact area hole corresponding to the first independent platform; and
a metal layer, plated on the surface of the protective layer and coupled to the first independent platform and the second independent platform, and the second independent platform forms a P electrode layer pad on the first independent platform.

2. The dual platform semiconductor laser device of claim 1, wherein the laser chip layer includes a substrate, a first distributed Bragg reflector (DBR) grown according to a continuous epitary and disposed at a distal surface of the substrate, an active area, and a second distributed Bragg reflector (DBR).

3. The dual platform semiconductor laser device of claim 1, wherein the first independent platform and the second independent platform are etched with a gap in between and formed on the second distributed Bragg reflector (DBR) of the laser chip layer.

4. The dual platform semiconductor laser device of claim 1, wherein the two independent platforms etched and formed on the laser chip layer include an oxide confined insulating area of the oxide layer and produce a light emitting active area to define an independent platform for the light emitting active area platform, and an oxide confined insulating area of the oxide layer produces another independent platform and defines an area for a wire bonding basis for a wire bonding platform.

5. The dual platform semiconductor laser device of claim 1, wherein the oxide layer is made of an oxidizing material by a portion of the oxidizing material together with an oxidation process.

6. The dual platform semiconductor laser device of claim 1, wherein the independent platform defined as a wire bonding platform is etched and formed by the second distributed Bragg reflector (DBR) of an ion implant process.

7. The dual platform semiconductor laser device of claim 1, wherein the independent platform defined as a wire bonding platform is etched and formed by a semiconductor structure produced by the second distributed Bragg reflector (DBR) of the laser chip layer.

8. The dual platform semiconductor laser device of claim 1, wherein the independent platform uses the oxide layer forming an insulating area to produce a light emitting active area structure of the oxide confined hole, and the other independent platform uses an oxide layer forming an insulating area to produce the basic platform pad for wire bonding the light emitting active area.

9. The dual platform semiconductor laser device of claim 1, wherein the independent platform defined as a wire bonding platform includes a top surface in a circular shape, a square shape, a trapezium shape, a rhombus shape, an annular shape, or an elliptic shape.

10. The dual platform semiconductor laser device of claim 1, wherein the dielectric layer is made of a dielectric material including a polymer material such as SOG, BCB, or polyimide.

11. The dual platform semiconductor laser device of claim 1, wherein the protective layer is made of silicon nitride (SiN) or silicon oxide (SiO2) and plated in form of a film on the surface of the dielectric layer.

12. The dual platform semiconductor laser device of claim 1, wherein the protective layer includes a contact area hole in a circular shape.

13. The dual platform semiconductor laser device of claim 1, wherein the protective layer includes a contact area hole in a continuous geometric shape including a square shape, a trapezium shape, a rhombus shape, or an elliptic shape.

14. The dual platform semiconductor laser device of claim 1, wherein the metal layer is plated onto a portion of the first independent platform and includes a light emitting hole, while the metal layer is penetrated through the contact area hole and coupled to the top surface of the first independent platform.

15. The dual platform semiconductor laser device of claim 1, wherein the metal layer includes a light emitting hole disposed in the hole diameter with a continuous geometric shape of the contact area hole and corresponding to an oxide confined hole of the light emitting active area platform to correspond to the active area of a light producing area to carry out a vertical light emission.

16. The dual platform semiconductor laser device of claim 1, wherein the metal layer is made of an electrically conductive material or an electrically conductive mixture.

17. An oxide confined dual platform semiconductor laser device, comprising:
a laser chip layer;
a first independent platform, etched and formed on the laser chip layer, and having an oxide confined insulating area;
a second independent platform, etched and formed on the laser chip layer, and having an oxide confined insulating area;
a dielectric layer, filled between the exteriors of the first independent platform and the second independent platform and on the surface of the laser chip layer to produce a planarized surface;
a protective layer, disposed on the surface of the dielectric layer, and including a contact area hole for exposing a portion of the first independent;
a metal layer, plated on the surface of the protective layer, and coupled to the first independent platform and the second independent platform to form a P electrode layer, and a P electrode layer pad disposed at the position of the second independent platform; and
a bottom electrode layer with a cathode layer coupled to the laser chip layer.

18. The oxide confined dual platform semiconductor laser device of claim 17, wherein the first independent platform etched and formed on the laser chip layer uses an oxide layer forming an oxide confined insulating area to produce a light emitting active area defined as a light emitting active area platform, and the second independent platform uses an oxide layer forming an oxide confined insulating area to produce a wire bonding platform area to define a wire bonding platform.

19. The oxide confined dual platform semiconductor laser device of claim 17, wherein the second independent platform with a top surface defined by the oxide confined insulating area and the top surface in a circular shape, a square shape, a trapezium shape, a rhombus shape, an annular shape, or an elliptic shape.

20. The oxide confined dual platform semiconductor laser device of claim 17, wherein the contact area hole defined at the protective layer is in a continuous geometric shape including a circular shape, a square shape, a trapezium shape, a rhombus shape, or an elliptic shape.

21. The oxide confined dual platform semiconductor laser device of claim 17, wherein the metal layer is plated onto a portion of the first independent platform and includes a light emitting hole and an oxide confined hole corresponding to the light emitting active area platform within the continuous geometric shaped hole of the contact area hole to correspond to an active area of a light producing area to carry out a vertical light emission.

22. An oxide confined dual platform semiconductor laser device, comprising:
a laser chip layer;
a light emitting active area platform, etched and formed on the laser chip layer;
a wire bonding platform, etched and formed on the laser chip layer as a P electrode pad;
an oxide layer, forming an oxide confined insulating area disposed at the light emitting active area platform and the wire boding platform;
a dielectric material, filled onto the surface of the laser chip layer between the exterior of the light emitting active area platform and the wire bonding platform for producing a planarized surface;
an insulating protective layer, formed on the surface of the dielectric material;
an electrically conductive material, disposed at the surface of the protective layer and coupled to the light emitting active area platform and the P electrode pad; and
a bottom electrode layer with a cathode layer coupled to the laser chip layer.

23. The oxide confined dual platform semiconductor laser device of claim 22, wherein the light emitting active area platform and the wire bonding platform are etched and formed with a gap in between and disposed on two independent platforms at a surface of the laser chip layer.

24. The oxide confined dual platform semiconductor laser device of claim 22, wherein the P electrode pad uses the wire bonding platform etched with the semiconductor structure as a forming basis to have a higher wire bonding strength.

25. The oxide confined dual platform semiconductor laser device of claim 22, wherein the protective layer includes a contact area hole corresponding to the light emitting active area platform for electrically coupling the light emitting active area platform and the electrically conductive material.

26. The oxide confined dual platform semiconductor laser device of claim 25, wherein the contact area hole of the protective layer is a continuous geometric shape such as a circular shape, a square shape, a trapezium shape, a rhombus shape, or an elliptic shape.

27. The oxide confined dual platform semiconductor laser device of claim 22, wherein the dielectric material is made of a polymer material including SOG, BCB, or polyimide to lower the wire connected metal capacitance.

28. The oxide confined dual platform semiconductor laser device of claim 22, wherein the insulating protective layer uses silicon nitride (SiN) or silicon oxide (SiO2) to plate a film on the dielectric material to form a planarized surface.

29. The oxide confined dual platform semiconductor laser device of claim 22, wherein the electrically conductive material includes a light emitting hole disposed at a portion of the first independent platform and in a continuous geometric shaped hole of the contact area hole and corresponding to the oxide confined hole of the light emitting active area platform to correspond to an active area of a light producing area to carry out a vertical light emission.

30. The oxide confined dual platform semiconductor laser device of claim 22, wherein the electrically conductive material is an electrically conductive material or an electrically conductive mixture.
